(19) United States
(12) Patent Application Publication
(10) Pub. No.: US 2024/0353755 A1
(43) Pub. Date: Oct. 24, 2024

(54) METHOD OF MANUFACTURING A SEMICONDUCTOR DEVICE

(71) Applicant: TAIWAN SEMICONDUCTOR MANUFACTURING COMPANY, LTD., Hsinchu (TW)

(72) Inventors: Shi-Cheng WANG, Hsinchu (TW); Cheng-Han Wu, Hsinchu (TW); Ching-Yu Chang, Hsinchu (TW); Ya-Ching Chang, Hsinchu (TW)

(21) Appl. No.: 18/137,288

(22) Filed: Apr. 20, 2023

(51) Int. Cl. G03F 7/11; G03F 7/004; H01L 21/027; H01L 21/033

(52) U.S. Cl. CPC G03F 7/11; G03F 7/0042; H01L 21/0274; H01L 21/0337

(57) ABSTRACT

A method includes forming a metallic resist layer over a substrate and patterning the metallic resist layer to form a metallic resist pattern over the substrate. An etch resistant layer composition including an inorganic component, an organic component, or a combination thereof is formed over the metallic resist pattern to form an etch resistant layer.

### BACKGROUND

As consumer devices have gotten smaller and smaller in response to consumer demand, the individual components of these devices have necessarily decreased in size as well. Semiconductor devices, which make up a major component of devices such as mobile phones, computer tablets, and the like, have been pressured to become smaller and smaller, with a corresponding pressure on the individual devices (e.g., transistors, resistors, capacitors, etc.) within the semiconductor devices to also be reduced in size.

One enabling technology that is used in the manufacturing processes of semiconductor devices is the use of photolithographic materials. Such materials are applied to a surface of a layer to be patterned and then exposed to an energy that has itself been patterned. Such an exposure modifies the chemical and physical properties of the exposed regions of the photosensitive material. This modification, along with the lack of modification in regions of the photosensitive material that were not exposed, can be exploited to remove one region without removing the other, or vice-verse.

However, as the size of individual devices has decreased, process windows for photolithographic processing has become tighter and tighter.

As the semiconductor industry has progressed into nanometer technology process nodes in pursuit of higher device density, higher performance, and lower costs, there have been challenges in reducing semiconductor feature size.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a process flow of manufacturing a semiconductor device according to embodiments of the disclosure.

FIGS. 2A and 2B show process stages of a sequential operation according to embodiments of the disclosure.

FIG. 3 shows a process stage of a sequential operation according to embodiments of the disclosure.

FIGS. 4A and 4B show process stages of a sequential operation according to an embodiment of the disclosure.

FIG. 5 shows a process stage of a sequential operation according to embodiments of the disclosure.

FIG. 6 shows a process stage of a sequential operation according to an embodiment of the disclosure.

FIGS. 7A and 7B show process stages of a sequential operation according to an embodiment of the disclosure.

FIGS. 8A and 8B show process stages of a sequential operation according to an embodiment of the disclosure.

FIG. 9 shows a process stage of a sequential operation according to an embodiment of the disclosure.

FIG. 10 shows a process stage of a sequential operation according to an embodiment of the disclosure.

FIG. 11A shows organometallic precursors according to embodiments of the disclosure. FIG. 11B shows a reaction the organometallic precursors undergo when exposed to actinic radiation. FIG. 11C shows examples of organometallic precursors according to embodiments of the disclosure.

FIG. 12 illustrates a deposition apparatus according to embodiments of the disclosure.

FIGS. 13A and 13B illustrate etch resistant components according to embodiments of the disclosure.

FIG. 14 illustrates the configuration of the components of an etch resistant layer composition according to embodiments of the disclosure.

FIG. 15 illustrates surfactant additives according to embodiments of the disclosure.

FIG. 16 illustrates photoacid generator additives according to embodiments of the disclosure.

FIG. 17A and FIG. 17B are diagrams of a controller according to some embodiments of the disclosure.

FIG. 18 shows a process stage of a sequential operation according to embodiments of the disclosure.

FIG. 19 shows a process stage of a sequential operation according to an embodiment of the disclosure.

FIGS. 20A and 20B show process stages of sequential operations according to embodiments of the disclosure.

FIG. 21 shows a process stage of a sequential operation according to an embodiment of the disclosure.

FIG. 22 shows a process stage of a sequential operation according to an embodiment of the disclosure.

FIGS. 23A and 23B show process stages of a sequential operation according to embodiments of the disclosure.

FIGS. 24A and 24B show process stages of a sequential operation according to embodiments of the disclosure.

FIG. 25 shows a process stage of a sequential operation according to an embodiment of the disclosure.

FIG. 26 shows a process stage of a sequential operation according to an embodiment of the disclosure.

### DETAILED DESCRIPTION

It is to be understood that the following disclosure provides many different embodiments, or examples, for implementing different features of the disclosure. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. In addition, the term “made of” may mean either “comprising” or “consisting of.” In the present disclosure, a phrase “one of A, B and C” means “A, B and/or C” (A, B, C, A and B, A and C, B and C, or A, B and C), and does not mean one element from A, one element from B and one element from C, unless otherwise described. In the present disclosure, a source and a drain are interchangeably used and may be referred to as a source/drain. Source/drain region(s) may refer to a source or a drain, individually or collectively dependent upon the context.

Improving the line width roughness (LWR) and reducing the exposure dose (EOP) are desirable in the field of photolithographic processing to continue scaling down the devices and efficiently increase semiconductor device yield. Deep ultraviolet (DUV), electron beam (e-beam) and extreme ultraviolet (EUV) lithography have been developed to decrease the critical dimension and increase device yield. EUV lithography has been developed for use in nanometer technology process nodes, such as below 40 nm process nodes. Organic polymer based photoresists are used in photolithography in some embodiments. However, C, N, and O atoms in the polymers of organic photoresists are weak in EUV photon absorption. It has been found that certain metals have higher EUV photon absorption. To use the higher EUV photon absorption of metals, metallic resist have been developed. In metallic photoresists, a reduction of the exposure dose is critical for throughput improvement. The dosage reduction affects the roughness and resolution of the pattern, in what is known as the RLS trade off (R=resolution (e.g.—critical dimension; L=line edge roughness (LER); and S=exposure dose). To avoid this RLS trade-off in metallic resist, a photoresist pattern treatment is disclosed herein.

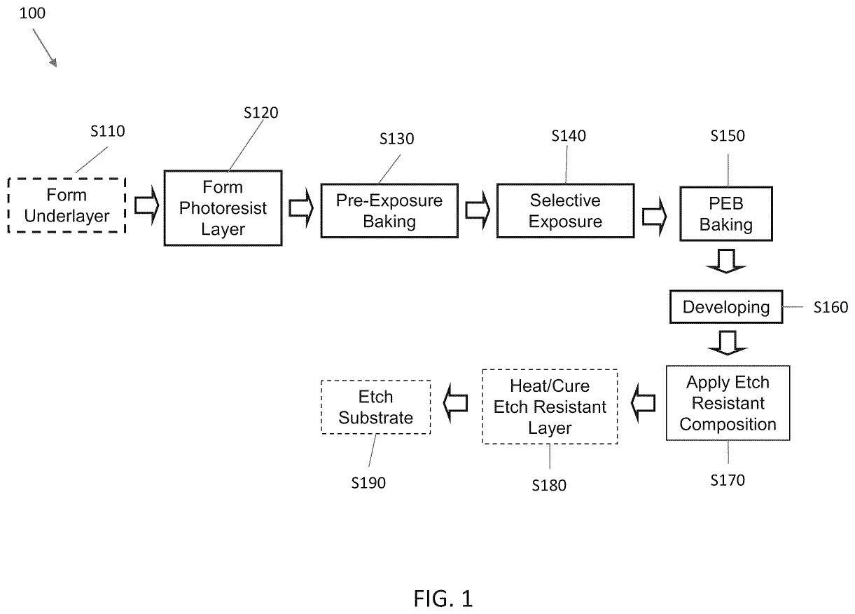

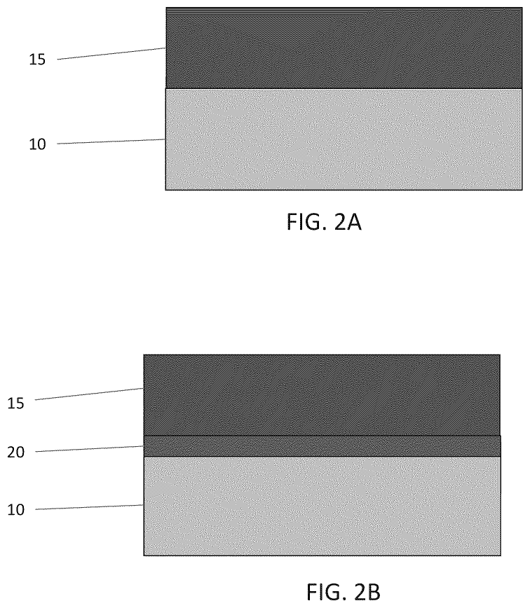

FIG. 1 illustrates a process flow 100 and FIGS. 2A-10 illustrate various stages of manufacturing a semiconductor device according to embodiments of the disclosure. A photoresist layer 15 is formed over a layer to be patterned (target layer) or substrate in operation S120, as shown in FIG. 2A. The photoresist layer 15 includes a metallic photoresist composition in some embodiments. In some embodiments, a resist underlayer composition is coated on a surface of a layer to be patterned (target layer) or a substrate 10 in operation S110, to form a resist underlayer 20 before forming the photoresist layer 15 in operation S110, as shown in FIG. 2B.

In some embodiments, the resist underlayer 20 has a thickness ranging from about 2 nm to about 300 nm. In some embodiments, the resist underlayer has a thickness ranging from about 20 nm to about 100 nm. The resist underlayer 20 undergoes a baking operation to evaporate solvents in the underlayer composition in some embodiments. The underlayer 20 is baked at a temperature and time sufficient to cure and dry the underlayer 20. In some embodiments, the underlayer is heated at a temperature in a range of about 80° C. to about 300° C. for about 10 seconds to about 10 minutes. In some embodiments, the underlayer is heated at a temperature ranging from about 160° C. to about 250° C. After forming the underlayer 20, a resist layer composition is subsequently coated on a surface of the resist underlayer 20 in operation S120, in some embodiments, to form a resist layer 15, as shown in FIG. 2B.

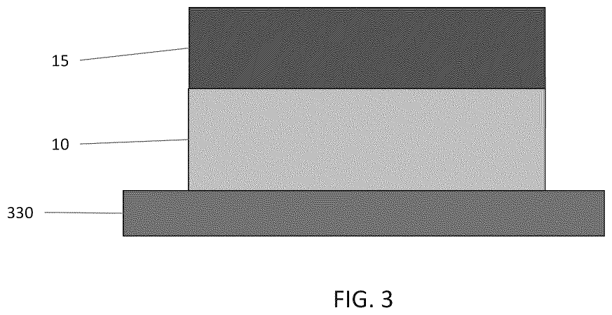

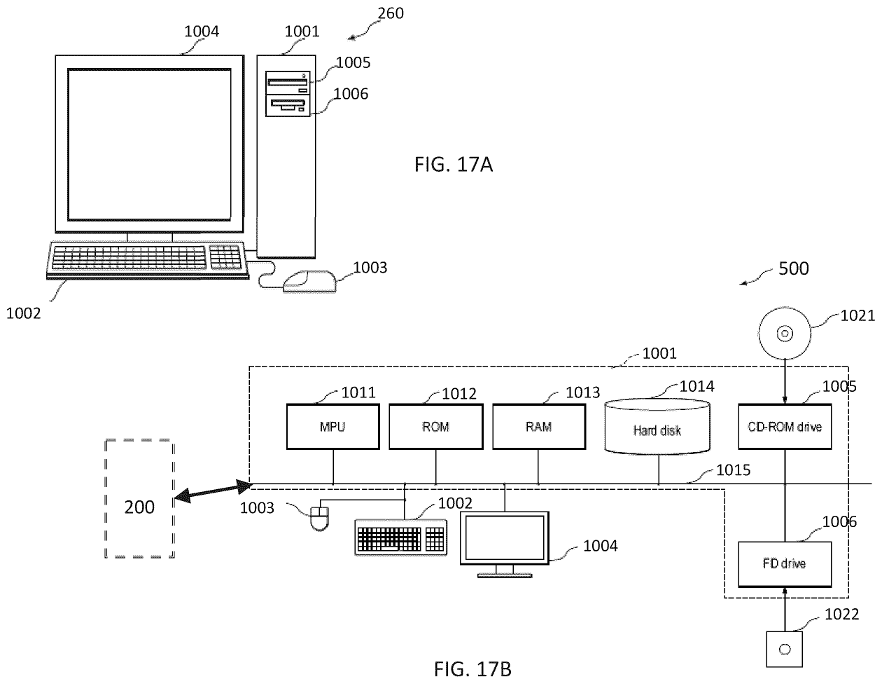

In some embodiments, a pre-exposure baking operation S130 is performed to drive off solvents in the photoresist layer 15 or to cure the photoresist layer 15. In some embodiments, the photoresist layer 15 is heated at a temperature ranging from about 40° C. to about 300° C. for about 10 seconds to about 10 minutes. In some embodiments, the heating is performed using a heater 330, as shown in FIG. 3. In some embodiments, the heater 330 is a hot plate, in other embodiments, radiant heating, such as infrared lamps, are used. The heating is controlled by a controller 260 (see FIGS. 17A, 17B) in some embodiments.

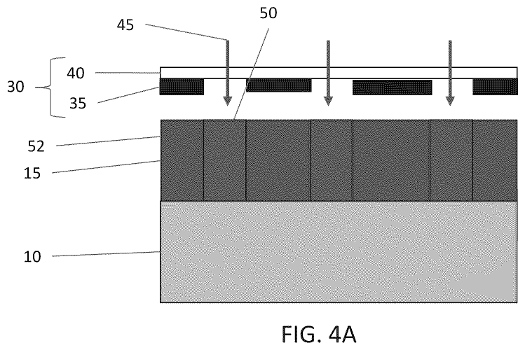

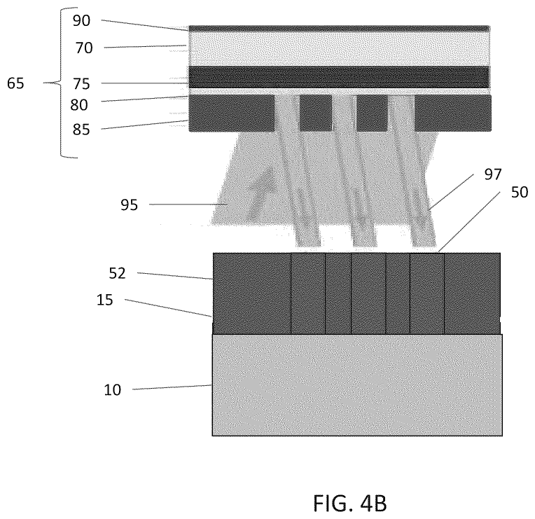

After the pre-exposure baking operations S130 of the photoresist layer 15, the photoresist layer 15 is selectively exposed to actinic radiation 45/97 (see FIGS. 4A and 4B) in operation S140. In some embodiments, the photoresist layer 15 is selectively exposed to ultraviolet radiation. In some embodiments, the radiation is electromagnetic radiation, such as g-line (wavelength of about 436 nm), i-line (wavelength of about 365 nm), ultraviolet radiation, deep ultraviolet radiation, extreme ultraviolet, electron beams, or the like. In some embodiments, the radiation source is selected from the group consisting of a mercury vapor lamp, xenon lamp, carbon arc lamp, a KrF excimer laser light (wavelength of 248 nm), an ArF excimer laser light (wavelength of 193 nm), an F₂ excimer laser light (wavelength of 157 nm), or a CO₂ laser-excited Sn plasma (extreme ultraviolet, wavelength of 13.5 nm).

As shown in FIG. 4A, the exposure radiation 45 passes through a photomask 30 before irradiating the photoresist layer 15 in some embodiments. In some embodiments, the photomask has a pattern to be replicated in the doped photoresist layer 15. The pattern is formed by an opaque pattern 35 on the photomask substrate 40, in some embodiments. The opaque pattern 35 may be formed by a material opaque to ultraviolet radiation, such as chromium, while the photomask substrate 40 is formed of a material that is transparent to ultraviolet radiation, such as fused quartz.

In some embodiments, the selective exposure of the photoresist layer 15 to form exposed regions 50 and unexposed regions 52 is performed using extreme ultraviolet lithography. In an extreme ultraviolet lithography operation, a reflective photomask 65 is used to form the patterned exposure light in some embodiments, as shown in FIG. 4B. The reflective photomask 65 includes a low thermal expansion glass substrate 70, on which a reflective multilayer 75 of Si and Mo is formed. A capping layer 80 and absorber layer 85 are formed on the reflective multilayer 75. A rear conductive layer 90 is formed on the back side of the low thermal expansion glass substrate 70. In extreme ultraviolet lithography, extreme ultraviolet radiation 95 is directed towards the reflective photomask 65 at an incident angle of about 6°. A portion 97 of the extreme ultraviolet radiation is reflected by the Si/Mo multilayer 75 towards the photoresist coated substrate 10, while the portion of the extreme ultraviolet radiation incident upon the absorber layer 85 is absorbed by the photomask. In some embodiments, additional optics, including mirrors, are between the reflective photomask 65 and the photoresist coated substrate.

The region 50 of the photoresist layer exposed to radiation undergoes a chemical reaction thereby changing its solubility in a subsequently applied developer relative to the region 52 of the photoresist layer not exposed to radiation. In some embodiments, the region 50 of the photoresist layer exposed to radiation undergoes a crosslinking reaction.

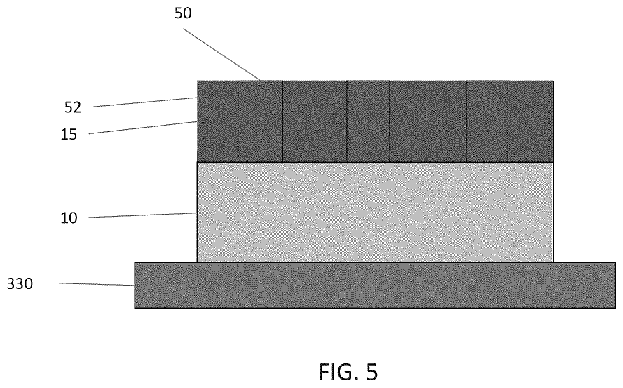

In some embodiments, a post exposure baking (PEB) operation S150 is performed, as shown in FIG. 5. In some embodiments, the photoresist layer 15 is heated at a temperature ranging from about 50° C. to about 300° C. during the post exposure baking operation S150. In some embodiments, the temperature is controlled using the heater 330 and a controller 260 (see FIGS. 17A, 17B). In some embodiments, the photoresist layer 15 is heated at a temperature ranging from about 50° C. to about 160° C. for about 20 s to about 120 s. The post-exposure baking may be used to assist in the generating, dispersing, and reacting of the acid/base/free radical generated from the impingement of the radiation 45/97 upon the photoresist layer 15 during the exposure. Such assistance helps to create or enhance chemical reactions, which generate chemical differences between the exposed region 50 and the unexposed region 52 within the photoresist layer.

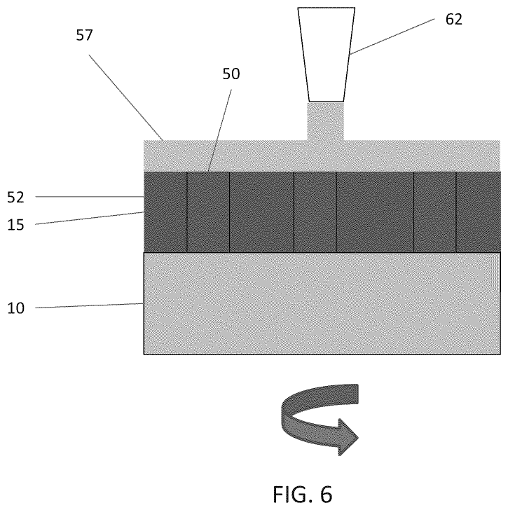

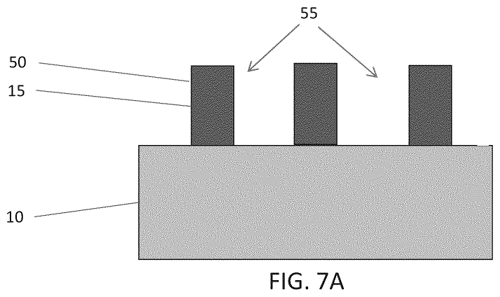

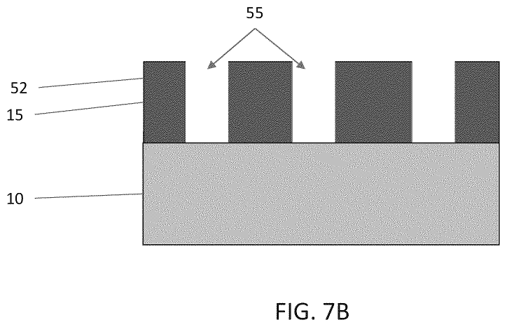

The selectively exposed photoresist layer is subsequently developed by applying a developer to the selectively exposed photoresist layer in operation S160. As shown in FIG. 6, a developer 57 is supplied from a dispenser 62 to the photoresist layer 15. In some embodiments, the unexposed region 52 of the photoresist layer is removed by the developer 57 forming a pattern of openings 55 in the photoresist layer 15 to expose the substrate 10, as shown in FIG. 7A, while in other embodiments, the exposed region 50 of the photoresist layer is removed by the developer 57 forming a pattern of openings 55 in the photoresist layer 15 to expose the substrate 10, as shown in FIG. 7B.

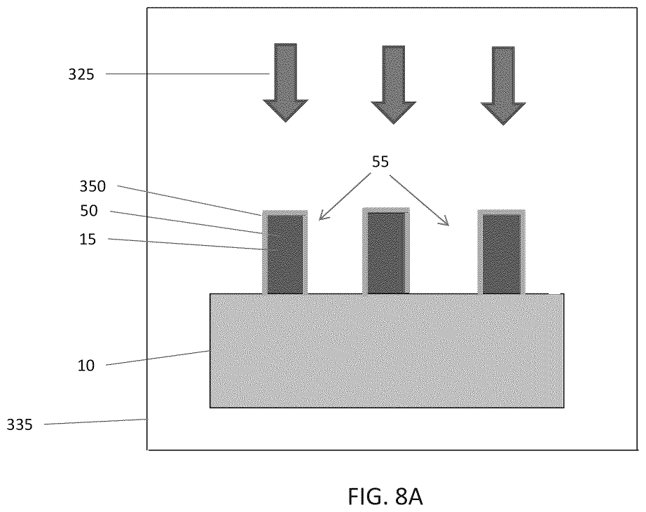

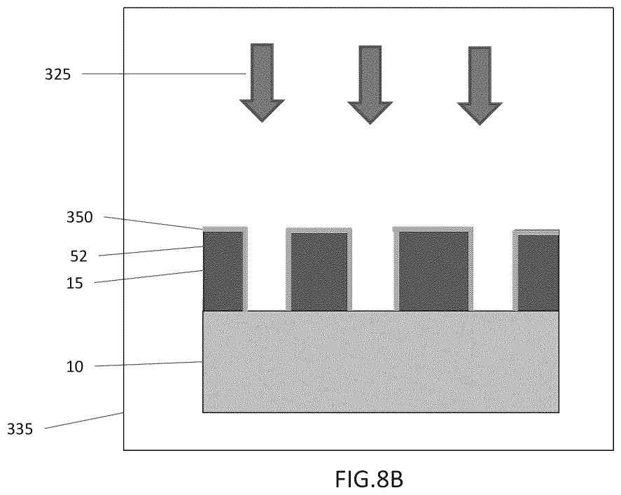

After the development operation S160, the photoresist pattern undergoes a post-development treatment operation S170 to strengthen or planarize the patterned photoresist features, as shown in FIGS. 8A and 8B. The post-development treatment operation S170 includes applying an etch resistant material composition 325 to the surface of the patterned photoresist features 15 to form an etch resistant layer 350 over the photoresist pattern features. In some embodiments, the etch resistant material layer 350 is formed by applying a liquid etch resistant material composition. In other embodiments, the etch resistant material layer 350 is formed by a vapor deposition operation in a vapor deposition chamber 335. In some embodiments, the etch resistant material layer has a thickness of about 0.1 nm to about 20 nm. In other embodiments, the etch resistant material layer has a thickness of about 0.5 nm to about 10 nm. In other embodiments, the thickness ranges from about 1 to about 5 nm. Etch resistant material thicknesses less than the disclosed range there may not provide sufficient photoresist strengthening. Etch resistant material thicknesses greater than the disclosed range may not provide any significant additional benefit.

In addition to strengthening the photoresist pattern to minimize pattern degradation during subsequent etching operations, the etch resistant layer composition planarizes sidewalls of the photoresist pattern features by filling surface irregularities, recesses, and concavities to provide improved pattern resolution. In some embodiments, the etch resistant layer composition preferentially binds or reacts with the photoresist pattern, and does not bind to the surface of the substrate or target layer. In some embodiments, because the etch resistant layer composition does not bind to the surface of the substrate or target layer, the etch resistant layer composition on the substrate is preferentially removed during a subsequent etching operation. In some embodiments, excess etch resistant layer composition is removed from the substrate or target layer by masking and etching operations. In other embodiments, excess etch resistant layer composition is removed from the substrate or target layer by a subsequent rinsing operation.

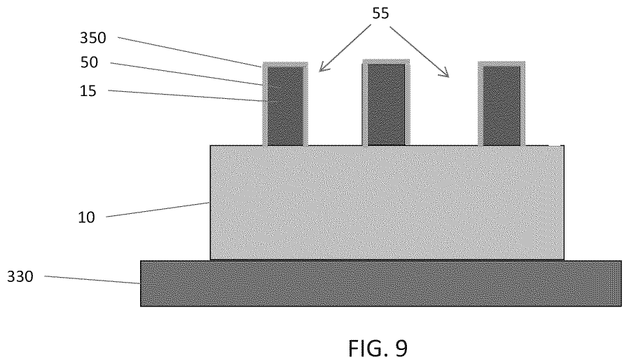

In some embodiments, the etch resistant layer 350 is subsequently heated in operation S180 to dry or cure the etch resistant layer 350, as shown in FIG. 9. In some embodiments, the heating operation is performed using a heater 330, such as a hot plate, though any suitable heating technique can be used. In some embodiments, the patterned photoresist layer and etch resistant layer are heated at temperature ranging from about 50° C. to about 300° C. during operation S180. In some embodiments, the temperature is controlled using the heater 330 and a controller 260 (see FIGS. 17A, 17B). In some embodiments, the photoresist layer and etch resistant layer are heated at a temperature ranging from about 100° C. to about 200° C. for about 20 s to about 120 s. In some embodiments, the heating operation S180 removes solvents from the etch resistant layer S180. In some embodiments, the heating operation S180 improves the adhesion of the etch resistant layer 350 to the photoresist layer 15. In some embodiments, the heating operation S180 causes the etch resistant layer 350 to react with the photoresist layer 15, such as by a cross-linking reaction. In some embodiments, the heating operation is performed using an infrared lamp or an ultraviolet lamp.

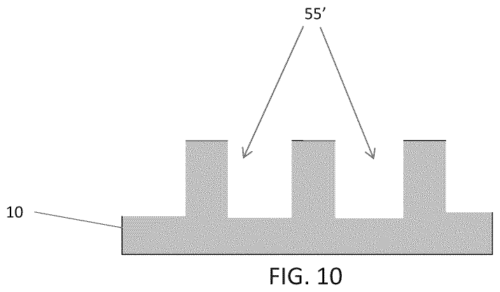

In some embodiments, the pattern of openings 55 in the patterned photoresist layer 15 is extended into the substrate 10 in operation S190 to create a pattern of openings 55′ in the substrate 10, thereby transferring the pattern in the photoresist layer 15 into the substrate 10, as shown in FIG. 10. The pattern is extended into the substrate by etching, using one or more suitable etchants. In some embodiments, the etching is anisotropic etching. In other embodiments, isotropic etching is performed. In some embodiments, the etchant is a gas, vapor, or a plasma. In other embodiments, the etchant is a liquid. The etch resistant layer 350 inhibits thinning of the photoresist pattern 15 during the etching operation S190, thereby providing etched patterns having improved control of the etched pattern dimensions and increased etch pattern accuracy. The etch resistant layer 350 and the photoresist layer pattern 15 are removed after etching the substrate 10 by using a suitable photoresist stripper solvent or by a plasma ashing operation.

In FIGS. 2A-10, in some embodiments, the substrate 10 includes a single crystalline semiconductor layer on at least it surface portion. The substrate 10 may include a single crystalline semiconductor material such as, but not limited to Si, Ge, SiGe, GaAs, InSb, GaP, GaSb, InAlAs, InGaAs, GaSbP, GaAsSb and InP. In some embodiments, the substrate 10 is a silicon layer of an SOI (silicon-on insulator) substrate. In certain embodiments, the substrate 10 is made of crystalline Si.

The substrate 10 may include in its surface region, one or more buffer layers (not shown). The buffer layers can serve to gradually change the lattice constant from that of the substrate to that of subsequently formed source/drain regions. The buffer layers may be formed from epitaxially grown single crystalline semiconductor materials such as, but not limited to Si, Ge, GeSn, SiGe, GaAs, InSb, GaP, GaSb, InAlAs, InGaAs, GaSbP, GaAsSb, GaN, GaP, and InP. In an embodiment, the silicon germanium (SiGe) buffer layer is epitaxially grown on the silicon substrate 10. The germanium concentration of the SiGe buffer layers may increase from 30 atomic % for the bottom-most buffer layer to 70 atomic % for the top-most buffer layer.

In some embodiments, the substrate 10 includes one or more layers of at least one metal, metal alloy, and metal nitride sulfide/oxide/silicide having the formula MXₐ, where M is a metal and X is N, S, Se, O, Si, and a is from about 0.4 to about 2.5. In some embodiments, the substrate 10 includes titanium, aluminum, cobalt, ruthenium, titanium nitride, tungsten nitride, tantalum nitride, and combinations thereof.

In some embodiments, the substrate 10 includes a dielectric having at least a silicon or metal oxide or nitride of the formula MX_{b}, where M is a metal or Si, X is N or O, and b ranges from about 0.4 to about 2.5. In some embodiments, the substrate 10 includes silicon dioxide, silicon nitride, aluminum oxide, hafnium oxide, lanthanum oxide, and combinations thereof.

In some embodiments, a resist underlayer 20 is formed over the substrate 10 before forming the photoresist layer 15. Resist underlayers 20 are made of polymer compositions disposed between the resist layer and the substrate to improve the adhesion of the resist layer to the substrate in some embodiments. In some embodiments, the resist underlayer 20 is a planarizing layer or bottom anti-reflective coating (BARC). In some embodiments, the BARC layer is an organic BARC, in other embodiments the BARC layer is an inorganic, such as a silicon-containing anti-reflective coating (SiARC) layer. In some embodiments, the underlayer composition includes an organic polymer, including, but not limited to polyhydroxystyrenes, polyacrylates, polymethacrylates, polyvinylphenols, polystyrenes, and copolymers thereof. In some embodiments, the organic polymer is a poly(4-hydroxystyrene), a poly(4-vinylphenol-co-methyl methacrylate) copolymer, and a poly(styrene)-b-poly(4-hydroxystyrene) copolymer. In some embodiments, the underlayer composition includes, inorganic polymers, such as a polysiloxane and polysiloxane derivatives. In some embodiments, the polysiloxane derivatives include functional groups, such as epoxy groups, amine groups, or thiol groups. In some embodiments, the underlayer 20 includes a bottom layer and a middle layer of a tri-layer resist. The bottom layer may include any of above-recited organic polymers and the middle layer may include a silicon-containing organic polymer. In other embodiments, the middle layer includes a siloxane polymer. In other embodiments, the middle layer includes silicon oxide (e.g., spin-on glass (SOG)), silicon nitride, silicon oxynitride, polycrystalline silicon, a metal-containing organic polymer material containing a metal such as titanium, titanium nitride, aluminum, and/or tantalum; and/or other suitable materials. The middle layer may be bonded to adjacent layers, such as by covalent bonding, hydrogen bonding, or hydrophilic-to-hydrophilic forces.

The photoresist layer 15 is a photosensitive layer that is patterned by exposure to actinic radiation. Typically, the chemical properties of the photoresist regions struck by incident radiation change in a manner that depends on the type of photoresist used. Photoresist layers 15 may be positive tone resists or negative tone resists. A positive tone resist refers to a photoresist material that when exposed to actinic radiation (e.g., UV light) becomes soluble in a developer, while the region of the photoresist that is non-exposed (or exposed less) is insoluble in the developer. A negative tone resist, on the other hand, refers to a photoresist material that when exposed to actinic radiation becomes insoluble in the developer, while the region of the photoresist that is non-exposed (or exposed less) is soluble in the developer. The region of a negative tone resist that becomes insoluble upon exposure to radiation may become insoluble due to a cross-linking reaction caused by the exposure to radiation. In some embodiments, the resist is a negative tone developed (NTD) resist. In an NTD resist, the portions of the photoresist layer exposed to actinic radiation do not crosslink, however, the developer is selected to selectively dissolve the unexposed portions of the photoresist layer, so that the exposed portions remain on the substrate.

In some embodiments of the present disclosure, a negative tone photoresist is exposed to actinic radiation. The exposed portions of the negative tone photoresist undergo crosslinking because of the exposure to actinic radiation, and during development, the unexposed, non-crosslinked portions of the photoresist are removed by the developer leaving the exposed regions of the photoresist remaining on the substrate. In other embodiments, an NTD resist used, wherein the exposed portions of the photoresist undergo a chemical reaction reducing the solubility of the exposed portions in the developer.

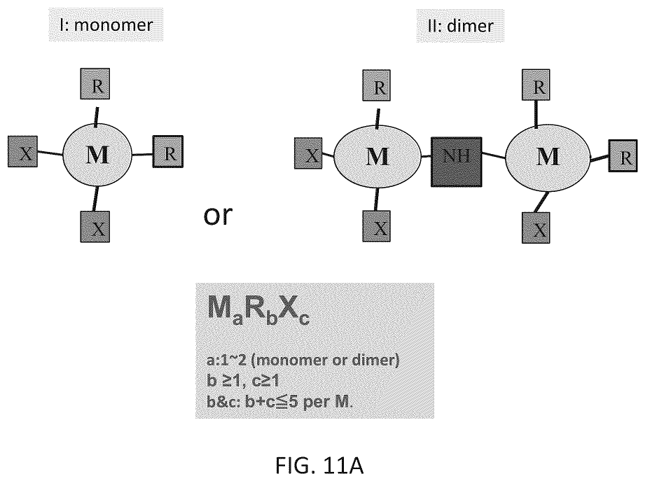

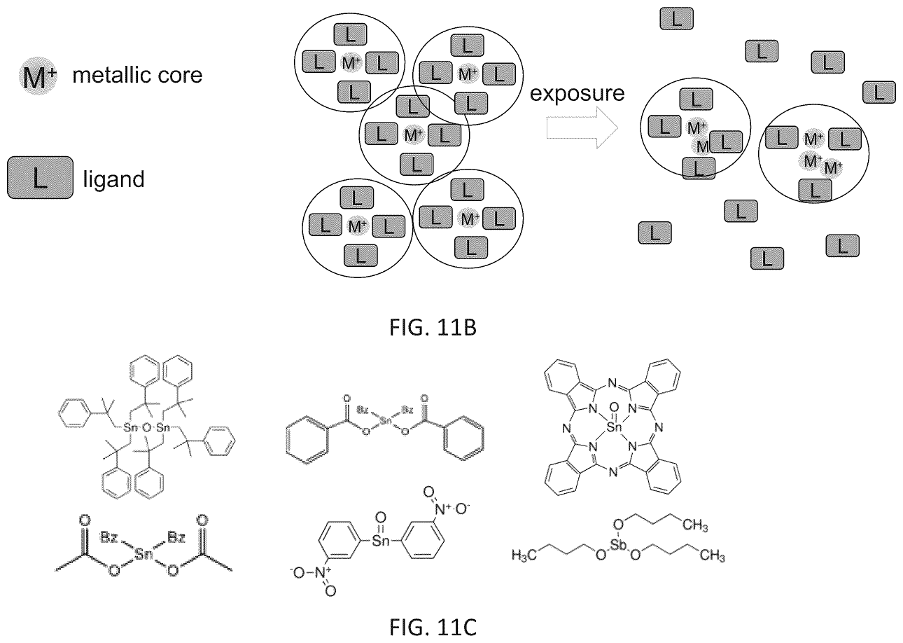

In some embodiments, the photoresist layer 15 is a negative tone metallic photoresist that undergoes a cross-linking reaction upon exposure to the radiation. In some embodiments, the photoresist layer 15 is made of a metallic photoresist composition, including a first compound or a first precursor and a second compound or a second precursor combined in a vapor state. The first precursor or first compound is an organometallic having a formula: MₐR_{b}X_{c}, as shown in FIG. 11A, where M is at least one of Sn, Bi, Sb, In, Te, Ti, Zr, Hf, V, Co, Mo, W, Al, Ga, Si, Ge, P, As, Y, La, Ce, or Lu; and R is a substituted or unsubstituted alkyl, alkenyl, or carboxylate group. In some embodiments, M is selected from the group consisting of Sn, Bi, Sb, In, Te, and combinations thereof. In some embodiments, R is a C3-C6 alkyl, alkenyl, or carboxylate. In some embodiments, R is selected from the group consisting of propyl, isopropyl, butyl, iso-butyl, sec-butyl, tert-butyl, pentyl, isopentyl, sec-pentyl, tert-pentyl, hexyl, iso-hexyl, sec-hexyl, tert-hexyl, and combinations thereof. X is a ligand, ion, or other moiety, which is reactive with the second compound or second precursor; and 1≤a≤2, b≥1, c≥1, and b+c≤5 in some embodiments. In some embodiments, the alkyl, alkenyl, or carboxylate group is substituted with one or more fluoro groups. In some embodiments, the organometallic precursor is a dimer, as shown in FIG. 11A, where each monomer unit is linked by an amine group. Each monomer has a formula: MₐR_{b}X_{c}, as defined above.

In some embodiments, R is alkyl, such as CₙH₂ₙ₊₁ where n≥3. In some embodiments, R is fluorinated, e.g., having the formula CₙFₓH₍₍₂ₙ₊₁₎₋ₓ₎. In some embodiments, R has at least one beta-hydrogen or beta-fluorine. In some embodiments, R is selected from the group consisting of i-propyl, n-propyl, t-butyl, i-butyl, n-butyl, sec-butyl, n-pentyl, i-pentyl, t-pentyl, and sec-pentyl, and combinations thereof.

In some embodiments, X is any moiety readily displaced by the second compound or second precursor to generate an M-OH moiety, such as a moiety selected from the group consisting of amines, including dialkylamino and monalkylamino; alkoxy; carboxylates, halogens, and sulfonates. In some embodiments, the sulfonate group is substituted with one or more amine groups. In some embodiments, the halide is one or more selected from the group consisting of F, Cl, Br, and I. In some embodiments, the sulfonate group includes a substituted or unsubstituted C1-C3 group.

In some embodiments, the first organometallic compound or first organometallic precursor includes a metallic core M⁺ with ligands L attached to the metallic core M⁺, as shown in FIG. 11B. In some embodiments, the metallic core M⁺ is a metal oxide. The ligands L include C3-C12 aliphatic or aromatic groups in some embodiments. The aliphatic or aromatic groups may be unbranched or branched with cyclic, or noncyclic saturated pendant groups containing 1-9 carbons, including alkyl groups, alkenyl groups, and phenyl groups. The branched groups may be further substituted with oxygen or halogen. In some embodiments, the C3-C12 aliphatic or aromatic groups include heterocyclic groups. In some embodiments, the C3-C12 aliphatic or aromatic groups are attached to the metal by an ether or ester linkage. In some embodiments, the C3-C12 aliphatic or aromatic groups include nitrite and sulfonate substituents.

In some embodiments, the organometallic precursor or organometallic compound include a sec-hexyl tris(dimethylamino) tin, t-hexyl tris(dimethylamino) tin, i-hexyl tris(dimethylamino) tin, n-hexyl tris(dimethylamino) tin, sec-pentyl tris(dimethylamino) tin, t-pentyl tris(dimethylamino) tin, i-pentyl tris(dimethylamino) tin, n-pentyl tris(dimethylamino) tin, sec-butyl tris(dimethylamino) tin, t-butyl tris(dimethylamino) tin, i-butyl tris(dimethylamino) tin, n-butyl tris(dimethylamino) tin, sec-butyl tris(dimethylamino) tin, i-propyl(tris)dimethylamino tin, n-propyl tris(diethylamino) tin, and analogous alkyl(tris)(t-butoxy) tin compounds, including sec-hexyl tris(t-butoxy) tin, t-hexyl tris(t-butoxy) tin, i-hexyl tris(t-butoxy) tin, n-hexyl tris(t-butoxy) tin, sec-pentyl tris(t-butoxy) tin, t-pentyl tris(t-butoxy) tin, i-pentyl tris(t-butoxy) tin, n-pentyl tris(t-butoxy) tin, t-butyl tris(t-butoxy) tin, i-butyl tris(butoxy) tin, n-butyl tris(butoxy) tin, sec-butyl tris(butoxy) tin, i-propyl(tris)dimethylamino tin, or n-propyl tris(butoxy) tin. In some embodiments, the organometallic precursors or organometallic compounds are fluorinated. In some embodiments, the organometallic precursors or compounds have a boiling point less than about 200° C.

In some embodiments, the first compound or first precursor includes one or more unsaturated bonds that can be coordinated with a functional group, such as a hydroxyl group, on the surface of the substrate or an intervening underlayer to improve adhesion of the photoresist layer to the substrate or underlayer.

In some embodiments, the second precursor or second compound is at least one of an amine, a borane, a phosphine, or water. In some embodiments, the amine has a formula NₚHₙXₘ, where 0≤n≤3, 0≤m≤3, n+m=3 when p is 1, and n+m=4 when p is 2, and each X is independently a halogen selected from the group consisting of F, Cl, Br, and I. In some embodiments, the borane has a formula BₚHₙXₘ, where 0≤n≤3, 0≤m≤3, n+m=3 when p is 1, and n+m=4 when p is 2, and each X is independently a halogen selected from the group consisting of F, Cl, Br, and I. In some embodiments, the phosphine has a formula PₚHₙXₘ, where 0≤n≤3, 0≤m≤3, n+m=3, when p is 1, or n+m=4 when p is 2, and each X is independently a halogen selected from the group consisting of F, Cl, Br, and I.

FIG. 11B shows metallic precursors undergoing a reaction as a result of exposure to actinic radiation in some embodiments. As a result of exposure to the actinic radiation, ligand groups L are split off from the metallic core M⁺ of the metallic precursors, and two or more metallic precursor cores bond with each other.

FIG. 11C shows examples of organometallic precursors according to embodiments of the disclosure. In FIG. 11C, Bz is a benzene group.

In some embodiments, the operation S120 of forming a photoresist layer is performed by a vapor phase deposition operation. In some embodiments, the vapor phase deposition operation includes atomic layer deposition (ALD) and chemical vapor deposition (CVD). In some embodiments, the ALD includes plasma-enhanced atomic layer deposition (PE-ALD); the CVD includes plasma-enhanced chemical vapor deposition (PE-CVD), metal-organic chemical vapor deposition (MO-CVD), atmospheric pressure chemical vapor deposition (AP-CVD), and low pressure chemical vapor deposition (LP-CVD).

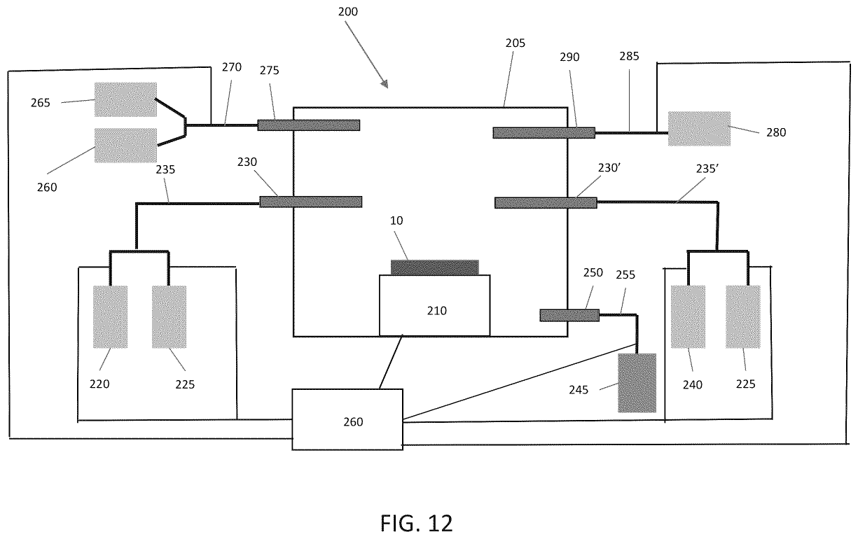

A resist layer deposition apparatus 200 according to some embodiments of the disclosure is shown in FIG. 12. In some embodiments, the deposition apparatus 200 is an ALD or CVD apparatus. The deposition apparatus 200 includes a vacuum chamber 205. A substrate support stage 210 in the vacuum chamber 205 supports a substrate 10, such as silicon wafer. In some embodiments, the substrate support stage 210 includes a heater. A first precursor or compound gas supply 220 and carrier/purge gas supply 225 are connected to an inlet 230 in the chamber via a gas line 235, and a second precursor or compound gas supply 240 and carrier/purge gas supply 225 are connected to another inlet 230′ in the chamber via another gas line 235′ in some embodiments. The chamber is evacuated, and excess reactants and reaction byproducts are removed by a vacuum pump 245 via an outlet 250 and exhaust line 255. In some embodiments, the flow rate or pulses of precursor gases and carrier/purge gases, evacuation of excess reactants and reaction byproducts, pressure inside the vacuum chamber 205, and temperature of the vacuum chamber 205 or wafer support stage 210 are controlled by a controller 260 configured to control each of these parameters.

Depositing a photoresist layer includes combining the first compound or first precursor and the second compound or second precursor in a vapor state to form the photoresist composition in some embodiments. In some embodiments, the first compound or first precursor and the second compound or second precursor of the photoresist composition are introduced into the deposition chamber 205 (CVD chamber) at about the same time via the inlets 230, 230′. In some embodiments, the first compound or first precursor and second compound or second precursor are introduced into the deposition chamber 205 (ALD chamber) in an alternating manner via the inlets 230, 230′, i.e.—first one compound or precursor then a second compound or precursor, and then subsequently alternately repeating the introduction of the one compound or precursor followed by the second compound or precursor.

In some embodiments, the deposition chamber 205 temperature ranges from about 30° C. to about 400° C. during the deposition operation, and between about 50° C. to about 250° C. in other embodiments. In some embodiments, the pressure in the deposition chamber 205 ranges from about 5 mTorr to about 100 Torr during the deposition operation, and between about 100 mTorr to about 10 Torr in other embodiments. In some embodiments, the plasma power is less than about 1000 W. In some embodiments, the plasma power ranges from about 100 W to about 900 W. In some embodiments, the flow rate of the first compound or precursor and the second compound or precursor ranges from about 100 sccm to about 1000 sccm. In some embodiments, the ratio of the flow of the organometallic compound precursor to the second compound or precursor ranges from about 1:1 to about 1:5. At operating parameters outside the above-recited ranges, unsatisfactory photoresist layers result in some embodiments. In some embodiments, the photoresist layer formation occurs in a single chamber (a one-pot layer formation).

In a CVD process according to some embodiments of the disclosure, two or more gas streams, in separate inlet paths 230, 235 and 230′, 235′, of an organometallic precursor and a second precursor are introduced to the deposition chamber 205 of a CVD apparatus, where they mix and react in the gas phase, to form a reaction product. The streams are introduced using separate injection inlets 230, 230′ or a dual-plenum showerhead in some embodiments. The deposition apparatus is configured so that the streams of organometallic precursor and second precursor are mixed in the chamber, allowing the organometallic precursor and second precursor to react to form a reaction product. Without limiting the mechanism, function, or utility of the disclosure, it is believed that the product from the vapor-phase reaction becomes heavier in molecular weight, and is then condensed or otherwise deposited onto the substrate 10.

In some embodiments, an ALD process is used to deposit the photoresist layer. During ALD, a layer is grown on a substrate 10 by exposing the surface of the substrate to alternate gaseous compounds (or precursors). In contrast to CVD, the precursors are introduced as a series of sequential, non-overlapping pulses. In each of these pulses, the precursor molecules react with the surface in a self-limiting way, so that the reaction terminates once all the reactive sites on the surface are consumed. Consequently, the maximum amount of material deposited on the surface after a single exposure to all of the precursors (a so-called ALD cycle) is determined by the nature of the precursor-surface interaction.

In an embodiment of an ALD process, an organometallic precursor is pulsed to deliver the metal-containing precursor to the substrate 10 surface in a first half reaction. In some embodiments, the organometallic precursor reacts with a suitable underlying species (for example OH or NH functionality on the surface of the substrate) to form a new self-saturating surface. Excess unused reactants and the reaction by-products are removed, by an evacuation-pump down using a vacuum pump 245 and/or by a flowing an inert purge gas in some embodiments. Then, a second precursor, such as ammonia (NH₃), is pulsed to the deposition chamber in some embodiments. The NH₃ reacts with the organometallic precursor on the substrate to obtain a reaction product photoresist on the substrate surface. The second precursor also forms self-saturating bonds with the underlying reactive species to provide another self-limiting and saturating second half reaction. A second purge is performed to remove unused reactants and the reaction by-products in some embodiments. Pulses of the first precursor and second precursor are alternated with intervening purge operations until a desired thickness of the photoresist layer is achieved.

In some embodiments, the first and second compounds or precursors are delivered into the deposition chamber 205 with a carrier gas. The carrier gas, a purge gas, a deposition gas, or other process gas may contain nitrogen, hydrogen, argon, neon, helium, or combinations thereof.

In some embodiments, the photoresist layer 15 is formed to a thickness of about 5 nm to about 50 nm, and to a thickness of about 10 nm to about 30 nm in other embodiments. A person of ordinary skill in the art will recognize that additional ranges of thicknesses within the explicit ranges above are contemplated and are within the present disclosure. The thickness can be evaluated using non-contact methods of x-ray reflectivity and/or ellipsometry based on the optical properties of the photoresist layers. In some embodiments, each photoresist layer thickness is relatively uniform to facilitate processing. In some embodiments, the variation in thickness of the deposited photoresist layer varies by no more than ±25% from the average thickness, in other embodiments each photoresist layer thickness varies by no more than ±10% from the average photoresist layer thickness. In some embodiments, such as high uniformity depositions on larger substrates, the evaluation of the photoresist layer uniformity may be evaluated with a 1 centimeter edge exclusion, i.e., the layer uniformity is not evaluated for portions of the coating within 1 centimeter of the edge. A person of ordinary skill in the art will recognize that additional ranges within the explicit ranges above are contemplated and are within the present disclosure.

In some embodiments, the organometallic compound includes tin (Sn), antimony (Sb), bismuth (Bi), indium (In), and/or tellurium (Te) as the metal component, however, the disclosure is not limited to these metals. In other embodiments, additional suitable metals include titanium (Ti), zirconium (Zr), hafnium (Hf), vanadium (V), cobalt (Co), molybdenum (Mo), tungsten (W), aluminum (Al), gallium (Ga), silicon (Si), germanium (Ge), phosphorus (P), arsenic (As), yttrium (Y), lanthanum (La), cerium (Ce), lutetium (Lu), or combinations thereof. The additional metals can be as alternatives to or in addition to the Sn, Sb, Bi, In, and/or Te.

The particular metal used may significantly influence the absorption of radiation. Therefore, the metal component can be selected based on the desired radiation and absorption cross section. Tin, antimony, bismuth, tellurium, and indium provide strong absorption of extreme ultraviolet light at 13.5 nm. Hafnium provides good absorption of electron beam and extreme UV radiation. Metal compositions including titanium, vanadium, molybdenum, or tungsten have strong absorption at longer wavelengths, to provide, for example, sensitivity to 248 nm wavelength ultraviolet light.

In some embodiments, the resist layer 15 is formed by mixing the organometallic compound in a solvent to form a resist composition and dispensing the resist composition onto the substrate 10. To aid in the mixing and dispensing of the photoresist, the solvent is chosen at least in part based upon the materials chosen for the metallic resist. In some embodiments, the solvent is chosen such that the organometallic is evenly dissolved into the solvent and dispensed upon the layer to be patterned.

In some embodiments, the resist solvent is an organic solvent, and includes any suitable solvent such as propylene glycol methyl ether acetate (PGMEA), propylene glycol monomethyl ether (PGME), 1-ethoxy-2-propanol (PGEE), γ-butyrolactone (GBL), cyclohexanone (CHN), ethyl lactate (EL), methanol, ethanol, propanol, n-butanol, acetone, dimethylformamide (DMF), isopropanol (IPA), tetrahydrofuran (THF), methyl isobutyl carbinol (MIBC), n-butyl acetate (nBA), 2-heptanone (MAK), formic acid, acetic acid, propanoic acid, butanoic acid, or the like.

As one of ordinary skill in the art will recognize, the materials listed and described above as examples of materials that may be used for the solvent component of the photoresist are merely illustrative and are not intended to limit the embodiments. Rather, any suitable material that dissolves the metallic photoresist material may be used to help mix and apply the photoresist. All such materials are fully intended to be included within the scope of the embodiments.

In some embodiments, the photoresist composition is applied using a process such as a spin-on coating process, a dip coating method, an air-knife coating method, a curtain coating method, a wire-bar coating method, a gravure coating method, a lamination method, an extrusion coating method, CVD, ALD, PVD, combinations of these, or the like. In some embodiments, the photoresist layer 15 thickness ranges from about 10 nm to about 300 nm.

After the photoresist layer 15 has been formed on the substrate 10 a pre-exposure baking operation S130 is performed, as discussed herein (see FIGS. 1 and 3), and the photoresist layer 15 is selectively exposed S140 to form an exposed region 50 and an unexposed region 52, as discussed herein, and shown in FIGS. 1, 4A and 4B. In some embodiments, the exposure to radiation is carried out by placing the photoresist coated substrate in a photolithography tool. The photolithography tool includes a photomask 30, 65 optics, an exposure radiation source to provide the radiation 45, 97 for exposure, and a movable stage for supporting and moving the substrate under the exposure radiation.

The selectively exposed doped photoresist layer 15 is subsequently post exposure baked S150 and then developed, as shown in FIGS. 1, 5 and 67. In some embodiments of the disclosure, the developer composition, includes: a first solvent having Hansen solubility parameters of 18>δₐ>3, 7>δₚ>1, and 7>δₕ>1; an organic acid having an acid dissociation constant, pKa, of −11<pKa<4; and a Lewis acid, wherein the organic acid and the Lewis acid are different. In some embodiments, the developer includes a base having a pKa of 40>pKa>9.5.

The units of the Hansen solubility parameters are (Joules/cm³)^{1/2} or, equivalently, MPa^{1/2} and are based on the idea that one molecule is defined as being like another if it bonds to itself in a similar way. δ_{d} is the energy from dispersion forces between molecules. δₚ is the energy from dipolar intermolecular force between the molecules. δₕ is the energy from hydrogen bonds between molecules. The three parameters, δ_{d}, δₚ, and δₕ, can be considered as coordinates for a point in three dimensions, known as the Hansen space. The nearer two molecules are in Hansen space, the more likely they are to dissolve into each other.

In some embodiments, the concentration of the first solvent ranges from about 60 wt. % to about 99 wt. % based on a total weight of the developer composition. In some embodiments, the concentration of the first solvent is greater than 60 wt. %. In other embodiments, the concentration of the first solvent ranges from about 70 wt. % to about 90 wt. % based on a total weight of the developer composition. In some embodiments, the first solvent is one or more of n-butyl acetate, methyl n-amyl ketone, hexane, heptane, and amyl acetate.

In some embodiments, the organic acid is one or more of ethanedioic acid, methanoic acid, 2-hydroxypropanoic acid, 2-hydroxybutanedioic acid, citric acid, uric acid, trifluoromethanesulfonic acid, benzenesulfonic acid, ethanesulfonic acid, methanesulfonic acid, and maleic acid. In some embodiments, the concentration of the organic acid is about 0.001 wt. % to about 30 wt. % based on a total weight of the developer composition.

In some embodiments, suitable bases for the photoresist developer composition 57 include an alkanolamine, a triazole, or an ammonium compound. In some embodiments, suitable bases include an organic base selected from the group consisting of monoethanolamine, monoisopropanolamine, 2-amino-2-methyl-1-propanol, 1H-benzotriazole, 1,2,4-triazole, 1,8-diazabicycloundec-7-ene, tetramethylammonium hydroxide, tetraethylammonium hydroxide, tetrapropylammonium hydroxide, and tetrabutylammonium hydroxide, and combinations thereof; or inorganic bases selected from the group consisting of ammonium hydroxide, ammonium sulfamate, ammonium carbamate, NaOH, KOH, LiOH, Ca(OH)₂, Ba(OH)₂, Na₂CO₃, NH₄OH, Mg(OH)₂, RbOH, CsOH, Sr(OH)₂ and combinations thereof or inorganic bases selected from the group consisting of ammonia, ammonium hydroxide, ammonium sulfamate, ammonium carbamate, and combinations thereof. In some embodiments, the concentration of the base is about 1 ppm to about 30 wt. % based on a total weight of the developer composition.

In some embodiments, the concentration of the Lewis acid is about 0.1 wt. % to about 15 wt. % based on a total weight of the developer composition, and in other embodiments, the concentration of the Lewis acid is about 1 wt. % to about 5 wt. % based on a total weight of the developer composition.

In some embodiments, the developer composition includes a second solvent having Hansen solubility parameters of 25>δ_{d}>13, 25>δₚ>3, and 30>δₕ>4, and the first solvent and the second solvent are different solvents. In some embodiments, the concentration of the second solvent ranges from about 0.1 wt. % to less than about 40 wt. % based on a total weight of the developer composition. In some embodiments, the second solvent is one or more of propylene glycol methyl ether, propylene glycol ethyl ether, γ-butyrolactone, cyclohexanone, ethyl lactate, methanol, ethanol, propanol, n-butanol, acetone, dimethyl formamide, acetonitrile, isopropanol, tetrahydrofuran, or acetic acid.

In some embodiments, the developer composition includes about 0.001 wt. % to about 30 wt. % of a chelate based on the total weight of the developer composition. In other embodiments, the developer composition includes about 0.1 wt. % to about 20 wt. % of the chelate based on the total weight of the developer composition. In some embodiments, the chelate is one or more of ethylenediaminetetraacetic acid (EDTA), ethylenediamine-N,N′-disuccinic acid (EDDS), diethylenetriaminepentaacetic acid (DTPA), polyaspartic acid, trans-1,2-cyclohexanediamine-N,N,N′,N′-tetraacetic acid monohydrate, ethylenediamine, or the like.

In some embodiments, the developer composition includes water or ethylene glycol at a concentration of about 0.001 wt. % to about 30 wt. % based on a total weight of the developer composition.

In some embodiments, the photoresist developer composition includes a surfactant in a concentration range of from about 0.001 wt. % to about less than 5 wt. % based on a total weight of the developer composition to increase the solubility and reduce the surface tension on the substrate. In other embodiments, the concentration of the surfactant ranges from about 0.01 wt. % to about 1 wt. % based on the total weight of the developer composition.

At concentrations of the developer composition components outside the disclosed ranges, developer composition performance and development efficiency may be reduced, leading to increased photoresist residue and scum in the photoresist pattern, and increased line width roughness and line edge roughness.

In some embodiments, the developer 57 is applied to the photoresist layer 15 using a spin-on process. In the spin-on process, the developer 57 is applied to the photoresist layer 15 from above the photoresist layer 15 while the photoresist coated substrate is rotated, as shown in FIG. 6. In some embodiments, the developer 57 is supplied at a rate of between about 5 ml/min and about 800 ml/min, while the photoresist coated substrate 10 is rotated at a speed of between about 100 rpm and about 2000 rpm. In some embodiments, the developer is at a temperature of between about 20° C. and about 75° C. during the development operation. The development operation continues for between about 10 seconds to about 10 minutes in some embodiments.

While the spin-on operation is one suitable method for developing the photoresist layer 15 after exposure, it is intended to be illustrative and is not intended to limit the embodiment. Rather, any suitable development operations, including dip processes, puddle processes, and spray-on methods, may alternatively be used. All such development operations are included within the scope of the embodiments.

During the development process, the developer composition 57 dissolves either the photoresist regions 52 not exposed to radiation or the photoresist regions 50 that were exposed to radiation depending on whether the photoresist is a negative tone or positive tone resist, as illustrated in FIGS. 7A and 7B, leaving behind well-defined exposed photoresist regions 50, 52, respectively.

The patterned photoresist layer 15 is subsequently treated in operation S170 after development to improve the etch resistance of the photoresist pattern, as shown in FIGS. 8A and 8B. In some embodiments, an etch resistant layer composition is formed over the developed photoresist pattern. The etch resistant layer composition may include a component that is resistant to etching. The component may be an organic component or an inorganic component. In some embodiments, the etch resistant component includes an inorganic three-dimensional (3D) structure, organometallic compounds, nanoparticles, precursors, monomers, oligomers, and polymers.

In some embodiments, the etch resistant layer composition maintains or reduces the desired critical dimension. For example, in the case of a negative tone resist, a low exposure dose may result in pattern features that are narrower than a desired target width. The application of the etch resistant layer increases the width of the photoresist pattern features, thereby providing the desired pattern target width. Similarly, when the space between photoresist features is at a minimum distance achievable by the photolithographic exposure and development operations, the space between photoresist features can be further reduced by forming the etch resistant layer.

In some embodiments, the etch resistant layer composition includes an inorganic component, an organic component, or a combination thereof. The organic component may be bound to the inorganic component. In some embodiments, the inorganic component includes one or more selected from the group consisting of silicon (Si), phosphorus (P), or a metal. In some embodiments, the metal includes tin (Sn), antimony (Sb), bismuth (Bi), indium (In), tellurium (Te), zinc (Zn), titanium (Ti), zirconium (Zr), hafnium (Hf), vanadium (V), cobalt (Co), molybdenum (Mo), tungsten (W), aluminum (Al), gallium (Ga), silicon (Si), germanium (Ge), arsenic (As), yttrium (Y), lanthanum (La), cerium (Ce), lutetium (Lu), and oxides thereof. In some embodiments, the metal is Sn, Hf, Zn, and oxides thereof.

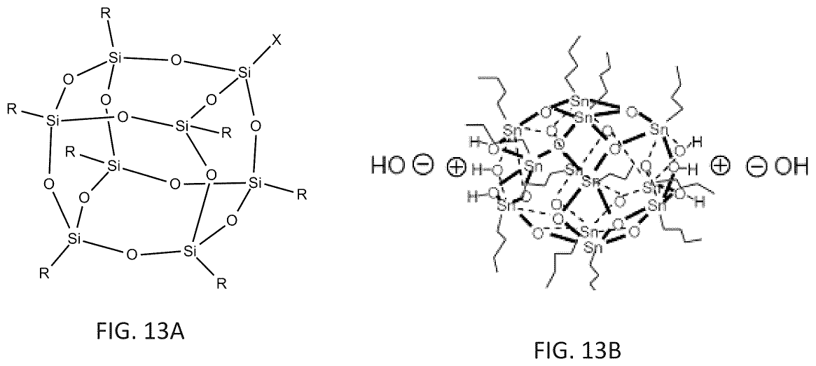

In some embodiments, the inorganic component has a three-dimensional (3D) cage structure. In some embodiments, the 3D structure is a silicon-based structure, such as a polyhedric oligomeric silsesquioxane, as shown in FIG. 13A. In other embodiments, the inorganic component is a metal-based structure, such as an Sn₁₂Oₓ structure, as shown in FIG. 13B.

In some embodiments, the etch resistant component is a silane-based material, such as a hydroxyalkyl silane. In some embodiments, the silane-based material includes one or more selected from the group consisting of Si(OH)ₓR_{y}; where R is a hydrogen or a C1-C20 alkyl group, x is an integer from 1 to 3, y is an integer from 1 to 3, and x+y=4. In some embodiments, the silane-based material includes one or more selected from the group consisting of [(CH₃)₃Si]₂NH, SiₓR¹_{y}(OR²)_{z}, SiₓR¹_{y}(NR²R³)_{z}, where x is an integer from 1 to 20; y and z are integers, where y+z=4x; and R1, R2, and R3 are independently H, a C1-C20 alkyl, and a C1-C20 fluoroalkyl. In some embodiments, at least one of R1, R2, and R3 is a linear, cyclic, or branched C1-C20 alkyl or linear, cyclic, or branched C1-C20 fluoroalkyl.

In some embodiments, the etch resistant component is a metal-based material, including M₄O_{z}, MRₓ(OR)_{y}; where M is any suitable metal, including Sn, Sb, Bi, In, Te, Zn, Ti, Zr, Hf, V, Co, Mo, W, Al, Ga, Si, Ge, As, Y, La, Ce, and Lu; x and y are integers from 0 to 4, x+y=4; and z ranges from 1 to 16. In some embodiments, the metal is Sn, Hf, or Zn. In some embodiments, the metal based material is one or more selected from MR¹_{y}(OR²)_{z}, and MₓR¹_{y}(NR²R³)_{z}; where M is any of the above metals, and where x is an integer from 1 to 20; y and z are integers, where y+z=4x; and R1, R2, and R3 are independently H, a C1-C20 alkyl, and a C1-C20 fluoroalkyl. In some embodiments, at least one of R1, R2, and R3 is a linear, cyclic, or branched C1-C20 alkyl or linear, cyclic, or branched C1-C20 fluoroalkyl. In some embodiments, the etch resistant component is SnR¹_{y}(OR²), or SnₓR¹_{y}(NR²R³)_{z}.

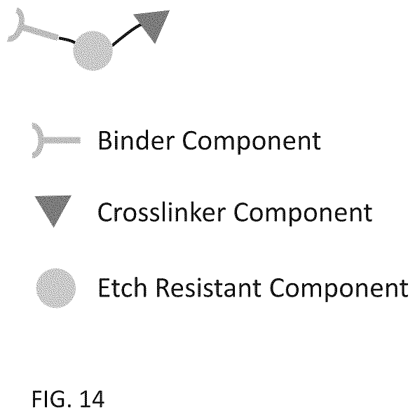

In some embodiments, the etch resistant material composition includes a combination of a binder component, or a crosslinker component, and the etch resistant component. The etch resistant component may be bound to the binder component or the crosslinker component, or the etch resistant component, binder component, and crosslinker component may all bound together, as shown in FIG. 14. The binder component increases adhesion of the etch resistant component to the photoresist layer. In some embodiments, the crosslinker reacts with a functional group in the photoresist layer and/or reacts with a functional group in the etch resistant layer to crosslink and bond the two structures together, thereby increasing the adhesion strength and etch resistance of the etch resistant layer.

In some embodiments, the binder component is an inorganic material, such a phosphonic acid or a phosphonic acid substituted with an organic group, such as C1-C20 hydrocarbon or a halogen substituted C1-C20 hydrocarbon. In some embodiments, the phosphonic acid is substituted with a C1-C20 alkyl group. In other embodiments, the binder component is any of the silane-based materials disclosed herein.

In some embodiments, the binder component is an organic material. In some embodiments, the organic binder material includes a ligand moiety and the ligand moiety is a monodentate ligand moiety, a bidentate ligand moiety, or a heteroatomic ligand moiety. The monodentate ligand moiety may have a functional group selected from the group consisting of —OH, —NH₂, —SH, —CN, an alkane, an alkene, and a piperazine; the bidentate ligand moiety may have one or more functional groups selected from the group consisting of —COOH, —CON(H)R, and a catechol; and the heteroatomic ligand moiety may have one or more groups selected from a pyridine group, a bipyridine group, a terpyridine group, a pyrrole group, an imidazole group, a purine group, a pyrimidine group, a pyrazine group, and a thiophene group.

In some embodiments, the crosslinker component is an organic material including one or more selected from the group consisting of an epoxy group, an oxetane group, a benzyl alcohol group, a benzyl ether group, an alkene group, an alkyne group, an acrylate group, a methacrylate group, and a melamine group.

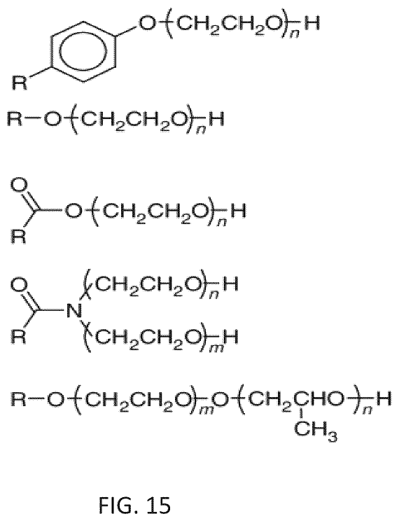

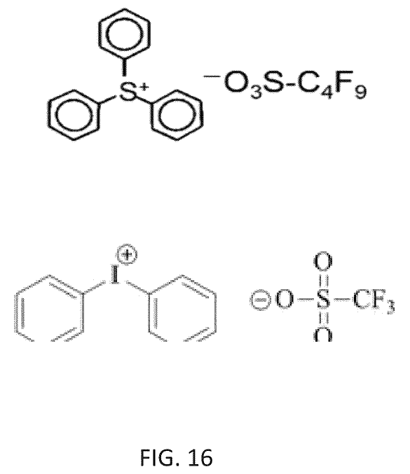

In some embodiments, the etch resistant layer composition includes one or more additives selected from a surfactant, a photoacid generator, a quencher, or a crosslinker. The surfactant may be one or more of the compounds shown in FIG. 15. In the compounds in FIG. 15, n and m range from 1 to 100 in some embodiments. The photoacid generator may be any suitable photoacid generator, including a sulfonium or iodonium. Examples of suitable photoacid generators include triphenyl sulfonium tert-perfluoro butyl sulfonate and diphenyl iodonium trifluoromethanesulfonate, as shown in FIG. 16. The quencher may be any suitable primary, secondary, or tertiary amine. The crosslinker may be any suitable organic compound having one or more of an epoxy group, an oxetane group, a benzyl alcohol group, a benzyl ether group, an alkene group, an alkyne group, an acrylate group, a methacrylate group, and a melamine group. In some embodiments, the crosslinker has the following structure:

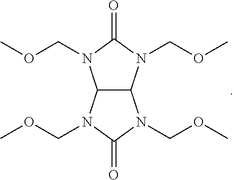

In other embodiments, the crosslinker has the following structure:

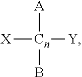

wherein C is carbon, n ranges from 1 to 15; A and B independently include a hydrogen atom, a hydroxyl group, a halide, an aromatic carbon ring, or a straight or cyclic alkyl, alkoxyl/fluoro, alkyl/fluoroalkoxyl chain having a carbon number of between 1 and 12, and each carbon C contains A and B; a first terminal carbon C at a first end of a carbon C chain includes X and a second terminal carbon C at a second end of the carbon chain includes Y, wherein X and Y independently include an amine group, a thiol group, a hydroxyl group, an isopropyl alcohol group, or an isopropyl amine group, except when n=1 then X and Y are bonded to the same carbon C. Specific examples of materials that may be used as the crosslinker include the following:

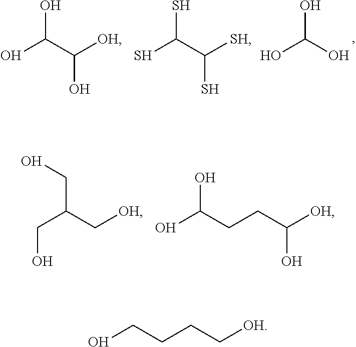

The amount of additive in the etch resistant layer composition ranges from about 0.1 wt. % to about 30 wt. % based on the total weight of the etch resistant component, binder component, crosslinker component, and additive component in some embodiments, and from 1 wt. % to 10 wt. % in other embodiments.

The etch resistant layer composition 325 may be applied to the patterned photoresist layer 15 by any suitable technique including a vapor deposition operation or it may be applied as liquid mixture, where the etch resistant layer composition is mixed in a suitable solvent.

The resist layer deposition apparatus 200 illustrated in FIG. 12 is also used to apply the etch resistant layer composition 325 to the patterned photoresist layer 15 in some embodiments. A etch resistant layer composition supply 260 and carrier gas supply 265 are connected to an inlet 275 in the chamber via a supply line 270. In some embodiments, the inlet 275 is configured to deliver the etch resistant layer composition 325 as a liquid spray or as an atomized vapor. In some embodiments, the etch resistant layer composition 325 is a gas. In some embodiments, a purge gas supply 280 is connected a purge gas inlet 290 via a gas supply line 285. In some embodiments, the chamber 205 is purged with the purge gas before the etch resistant gas composition 325 is introduced into the chamber 205. In some embodiments, the flow rate of the etch resistant layer composition, carrier gas, or purge gas are also controlled by the controller 260 configured to control each of these parameters, along with the flow rate of the precursor gases and carrier/purge gases, evacuation of excess reactants and reaction byproducts, pressure inside the vacuum chamber 205, and temperature of the vacuum chamber 205 or wafer support stage 210.

In some embodiments, the formation of the etch resistant layer uses a plurality of reactant gases, similar to the formation of the photoresist layer. In some embodiments, the operating parameter ranges of the vapor deposition apparatus 200 during the formation of the etch resistant layer are within the same range or similar to the operating ranges during the photoresist layer formation. In some embodiments, the etch resistant layer formation S170 is performed in a different vapor deposition apparatus than the photoresist layer formation operation S120. The etch resistant layer can be formed by any of the CVD or ALD techniques disclosed herein.

In some embodiments, the etch resistant layer composition 325 is applied to the photoresist layer 15 in the form of a liquid. In some embodiments, the etch resistant layer 350 is formed by mixing the etch resistant material components in a solvent and dispensing the mixture composition onto the patterned photoresist layer. To aid in the mixing and dispensing of the etch resistant layer composition, the solvent is chosen at least in part based upon the materials chosen for the etch resistant layer composition. In some embodiments, the solvent is chosen such that the components of the etch resistant layer composition are evenly dissolved into the solvent.

In some embodiments, the etch resistant layer composition solvent is an organic solvent, and includes any suitable solvent such as propylene glycol methyl ether acetate (PGMEA), propylene glycol monomethyl ether (PGME), 1-ethoxy-2-propanol (PGEE), Y-butyrolactone (GBL), cyclohexanone (CHN), ethyl lactate (EL), methanol, ethanol, propanol, n-butanol, acetone, dimethylformamide (DMF), isopropanol (IPA), tetrahydrofuran (THF), methyl isobutyl carbinol (MIBC), n-butyl acetate (nBA), 2-heptanone (MAK), formic acid, acetic acid, propanoic acid, butanoic acid, 5-15 carbon alkyl chain solvents, including n-pentane, cyclohexane, 2,2-dimethylpentane, 2,4-dimethylpentane, and the like. In some embodiments, the solvent includes water.

In some embodiments, the etch resistant layer composition 325 is applied to the patterned photoresist layer 15 by a spin coating technique. In other embodiments, the etch resistant layer composition 325 is applied by a spray coating technique. In other embodiments, the patterned photoresist layer 15 is dipped or immersed in a liquid solution of the etch resistant layer composition 325.

After forming the etch resistant layer in operation S170, the etch resistant layer 350 and patterned photoresist layer are heated in operation S180 in some embodiments, as shown in FIG. 9. The heating operation S180 may dry or cure the etch resistant layer 350. In some embodiments, the heating operation S180 advances the crosslinking of the etch resistant layer 350 and the photoresist layer 15, thereby strengthening the etch resistant layer 350. Subsequent operations, such as etching the substrate S190, are performed while the patterned photoresist layer 15 is in place. The etching operation, using dry or wet etching, is performed in some embodiments, to transfer the pattern of the photoresist layer 15 to the underlying substrate 10, forming recesses 55′ as shown in FIG. 10.

In some embodiments, the controller 260 is a computer system. FIG. 17A and FIG. 17B illustrate a computer system 260 for controlling a deposition apparatus 200 and its components in accordance with various embodiments of the disclosure. The controller 260 can also be used to control the heating operations S130, S150, and S180, the photolithographic operations S140, and the development operations S160. FIG. 17A is a schematic view of the computer system 260 that controls the deposition apparatus 200 and its components. In some embodiments, the computer system 260 is programmed to monitor and control the flow rate of the precursor gases and carrier/purge gases, evacuation of excess reactants and reaction byproducts, pressure inside the vacuum chamber 205, temperature of the vacuum chamber 205 or wafer support stage 210, and the flow rates of the photoresist precursors, etch resistant layer composition components, and carrier and purge gasses.

As shown in FIG. 17A, the computer system 260 is provided with a computer 1001 including an optical disk read only memory (e.g., CD-ROM or DVD-ROM) drive 1005 and a magnetic disk drive 1006, a keyboard 1002, a mouse 1003 (or other similar input device), and a monitor 1004 in some embodiments.

FIG. 17B is a diagram showing an internal configuration of the computer system 260. In FIG. 17B, the computer 1001 is provided with, in addition to the optical disk drive 1005 and the magnetic disk drive 1006, one or more processors 1011, such as a micro-processor unit (MP) or a central processing unit (CPU); a read-only memory (ROM) 1012 in which a program, such as a boot up program is stored; a random access memory (RAM) 1013 that is connected to the processors 1011 and in which a command of an application program is temporarily stored, and a temporary electronic storage area is provided; a hard disk 1014 in which an application program, an operating system program, and data are stored; and a data communication bus 1015 that connects the processors 1011, the ROM 1012, and the like. Note that the computer 1001 may include a network card (not shown) for providing a connection to a computer network such as a local area network (LAN), wide area network (WAN) or any other useful computer network for communicating data used by the computer system 260 and the deposition apparatus 200. In various embodiments, the controller 260 communicates via wireless or hardwired connection to the deposition apparatus 200, its components, and other tools used in the semiconductor device manufacturing operations.

The programs for causing the computer system 260 to execute the method for controlling the deposition apparatus 200 and its components are stored in an optical disk 1021 or a magnetic disk 1022, which is inserted into the optical disk drive 1005 or the magnetic disk drive 1006, and transmitted to the hard disk 1014. Alternatively, the programs are transmitted via a network (not shown) to the computer system 500 and stored in the hard disk 1014. At the time of execution, the programs are loaded into the RAM 1013. The programs are loaded from the optical disk 1021 or the magnetic disk 1022, or directly from a network in various embodiments.

The stored programs do not necessarily have to include, for example, an operating system (OS) or a third-party program to cause the computer 1001 to execute the methods disclosed herein. The program may only include a command portion to call an appropriate function (module) in a controlled mode and obtain desired results in some embodiments. In various embodiments described herein, the controller 260 is in communication with the deposition apparatus 200 to control various functions thereof.

The controller 260 is coupled to the deposition apparatus 200 including a pressure compensator in various embodiments. The controller 260 is configured to provide control data to those system components and receive process and/or status data from those system components. For example, in some embodiments, the controller 260 comprises a microprocessor, a memory (e.g., volatile or non-volatile memory), and a digital I/O port capable of generating control voltages sufficient to communicate and activate inputs to the processing system, as well as monitor outputs from the deposition apparatus 200. In addition, a program stored in the memory is utilized to control the aforementioned components of the deposition apparatus 200 according to a process recipe. Furthermore, the controller 260 is configured to analyze the process and/or status data, to compare the process and/or status data with target process and/or status data, and to use the comparison to change a process and/or control a system component. In addition, the controller 260 is configured to analyze the process and/or status data, to compare the process and/or status data with historical process and/or status data, and to use the comparison to predict, prevent, and/or declare a fault or alarm.

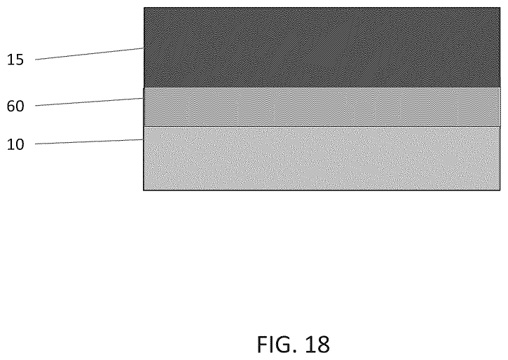

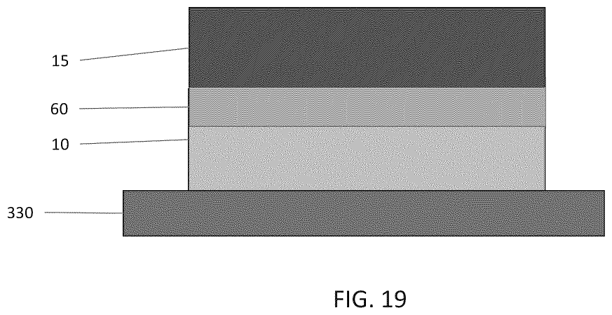

In some embodiments, a layer to be patterned (target layer) 60 is disposed over the substrate prior to forming the photoresist layer 15, as shown in FIG. 18. Pre-exposure baking/cooling operations S130 are performed, as necessary to dry and cure the photoresist layer 15, as shown in FIG. 19, and discussed herein in reference to FIGS. 1 and 3. In some embodiments, the target layer 60 is a metallization layer or a dielectric layer, such as a passivation layer, disposed over a metallization layer. In embodiments where the target layer 60 is a metallization layer, the target layer 60 is formed of a conductive material using metallization processes, and metal deposition techniques, including chemical vapor deposition, atomic layer deposition, and physical vapor deposition (sputtering). Likewise, if the target layer 60 is a dielectric layer, the target layer 60 is formed by dielectric layer formation techniques, including thermal oxidation, CVD, ALD, and PVD.

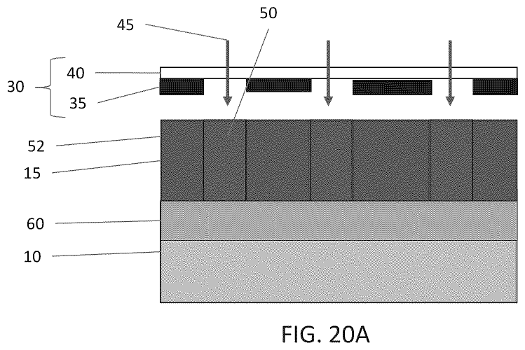

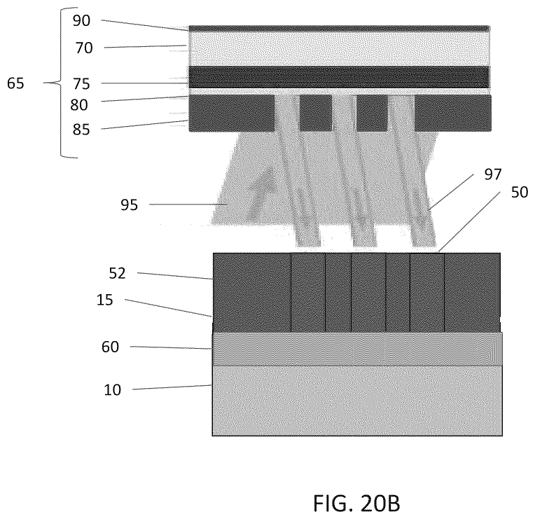

The photoresist layer 15 is subsequently selectively exposed to actinic radiation 45, 97 in operation S140 to form exposed regions 50 and unexposed regions 52 in the photoresist layer, as shown in FIGS. 20A and 20B, and described herein in relation to FIGS. 4A and 4B. As explained herein when the photoresist is a negative photoresist, crosslinking occurs in the exposed regions 50 in some embodiments.

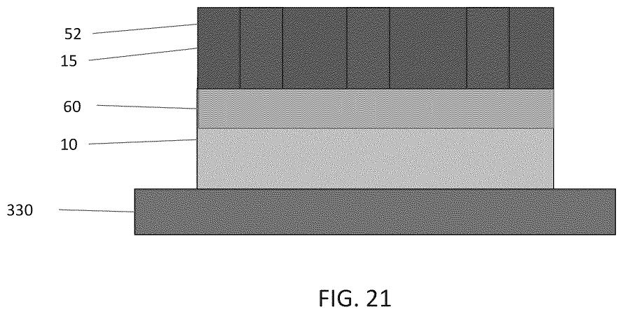

As shown in FIG. 21, a post exposure baking operations S150 is subsequently performed, as described herein in relation to FIG. 5.

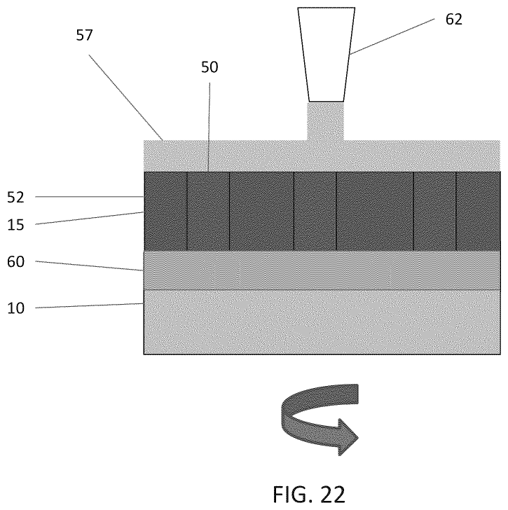

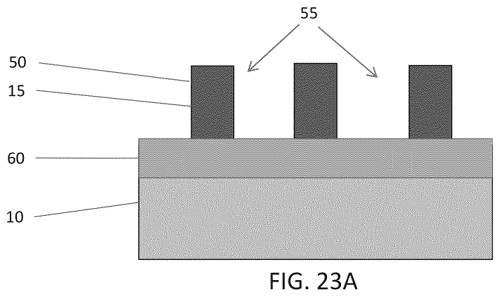

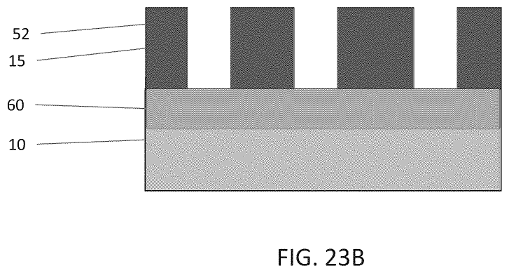

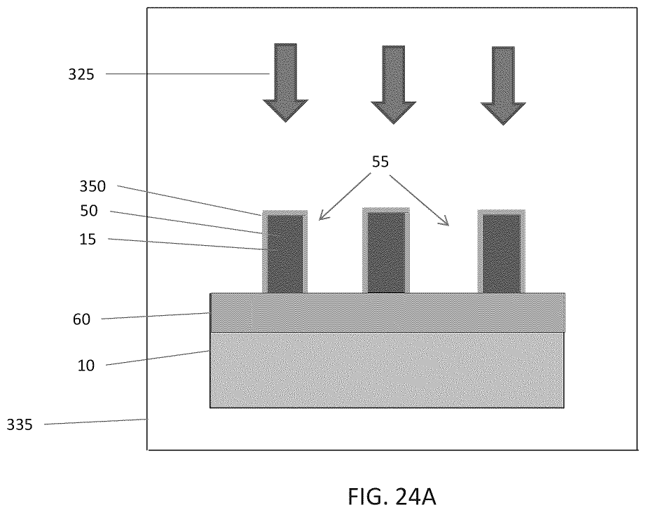

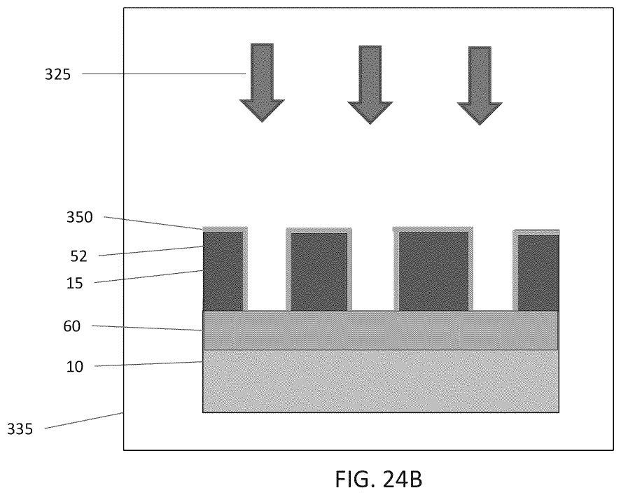

As shown in FIG. 22, the selectively exposed photoresist layer 50, 52 is subsequently developed by dispensing developer 57 from a dispenser 62 in operation S160 to form a pattern of photoresist openings 55, as shown in FIGS. 23A and 23B. The development operation is similar to that explained with reference to FIGS. 6, 7A, and 7B, herein. In some embodiments, the etch resistant layer composition 325 is applied to the developed photoresist pattern 15 in operation S170, as shown in FIGS. 24A and 24B, and as discussed herein in relation to FIGS. 8A and 8B.

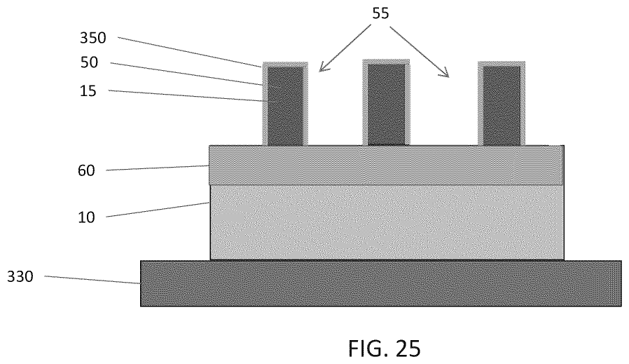

As shown in FIG. 25, the etch resistant layer 350 and patterned photoresist layer 15 are subsequently heated in operation S180 in some embodiments, and as discussed herein in relation to FIG. 9.

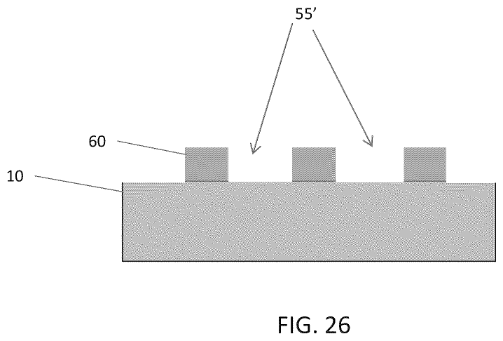

Then as shown in FIG. 26, the pattern 55 in the photoresist layer 15 is transferred to the target layer 60 using an etching operation and the photoresist layer is removed, as explained with reference to FIG. 10 to form pattern 55′ in the target layer 60.

Other embodiments include other operations before, during, or after the operations described above. In some embodiments, the disclosed methods include forming fin field effect transistor (FinFET) structures. In some embodiments, a plurality of active fins are formed on the semiconductor substrate. Such embodiments, further include etching the substrate through the openings of a patterned hard mask to form trenches in the substrate; filling the trenches with a dielectric material; performing a chemical mechanical polishing (CMP) process to form shallow trench isolation (STI) features; and epitaxy growing or recessing the STI features to form fin-like active regions. In some embodiments, one or more gate electrodes are formed on the substrate. Some embodiments include forming gate spacers, doped source/drain regions, contacts for gate/source/drain features, etc. In other embodiments, a target pattern is formed as metal lines in a multilayer interconnection structure. For example, the metal lines may be formed in an inter-layer dielectric (ILD) layer of the substrate, which has been etched to form a plurality of trenches. The trenches may be filled with a conductive material, such as a metal; and the conductive material may be polished using a process such as chemical mechanical planarization (CMP) to expose the patterned ILD layer, thereby forming the metal lines in the ILD layer. The above are non-limiting examples of devices/structures that can be made and/or improved using the method described herein.

In some embodiments, active components such diodes, field-effect transistors (FETs), metal-oxide semiconductor field effect transistors (MOSFET), complementary metal-oxide semiconductor (CMOS) transistors, bipolar transistors, high voltage transistors, high frequency transistors, FinFETs, gate all around FETs (GAA FETs), other three-dimensional (3D) FETs, other memory cells, and combinations thereof are formed, according to embodiments of the disclosure.

The novel etch resistant layer and etch resistant layer application techniques and semiconductor manufacturing methods according to the present disclosure provide higher semiconductor device feature density with reduced defects in a higher efficiency process than conventional methods. The novel techniques and methods enable a photolithographic operation at a reduced exposure dose and improved device throughput while maintaining high pattern resolution. The novel techniques and methods further provide improved line edge roughness, improved line width roughness, and a decrease in the critical dimension at lower exposure doses than conventional photolithographic techniques. The present disclosure allows the photoresist pattern critical dimension to be maintained or reduced. The present disclosure further enables improved control of etched pattern features in substrates, and increased accuracy and reproducibility of the patterns formed in the substrates.

An embodiment of the disclosure is a method, including forming a metallic resist layer over a substrate, and patterning the metallic resist layer to form a metallic resist pattern over the substrate. An etch resistant layer composition including an inorganic component, an organic component, or combination thereof is applied over the metallic resist pattern to form an etch resistant layer. In an embodiment, the etch resistant layer includes a combination of the inorganic component and the organic component, and the organic component is bound to the inorganic component. In an embodiment, the etch resistant layer includes the inorganic component and the inorganic component includes one or more selected from the group consisting of silicon, phosphorus, or a metal. In an embodiment, the inorganic component includes the metal, and the metal includes one or more selected from the group consisting of Sn, Sb, Bi, In, Te, Zn, Ti, Zr, Hf, V, Co, Mo, W, Al, Ga, Si, Ge, As, Y, La, Ce, and Lu. In an embodiment, the etch resistant layer includes the inorganic component and the inorganic component has a three-dimensional cage structure. In an embodiment, the etch resistant layer includes the inorganic component and the inorganic component includes one or more selected from the group consisting of a polyhedric oligomeric silsesquioxane, a silane, a phosphonic acid, a metal oxide, a metal oxide cage structure, and an organometallic. In an embodiment, the etch resistant layer includes the inorganic component and the inorganic component includes one or more selected from the group consisting of [(CH₃)₃Si]₂NH, SiₓR¹_{y}(OR²)_{z}, SiₓR¹_{y}(NR²R³)_{z}, SnR¹_{y}(OR²)_{z}, and SnₓR¹_{y}(NR²R³)_{z}; where x is an integer from 1 to 20; y and z are integers, where y+z=4x; and R1, R2, and R3 are independently H, a C1-C20 alkyl, and a C1-C20 fluoroalkyl. In an embodiment, at least one of R1, R2, and R3 is a linear, cyclic, or branched C1-C20 alkyl or linear, cyclic, or branched C1-C20 fluoroalkyl. In an embodiment, the etch resistant layer includes the organic component and the organic component includes a crosslinker moiety including one or more selected from the group consisting of an epoxy group, an oxetane group, a benzyl alcohol group, a benzyl ether group, an alkene group, an alkyne group, an acrylate group, a methacrylate group, and a melamine group. In an embodiment, the etch resistant layer composition includes a surfactant, a photoacid generator, a quencher, or a crosslinker.

Another embodiment of the disclosure is a method of manufacturing a semiconductor device, including forming a photoresist layer over a substrate and selectively exposing the photoresist layer to actinic radiation to form a latent pattern in the photoresist layer. The latent pattern is developed by applying a developer composition to the selectively exposed photoresist layer to form a patterned photoresist layer, and an etch resistant material layer is formed over the patterned photoresist layer. In an embodiment, the etch resistant material layer is formed by a vapor deposition operation. In an embodiment, the method includes heating the etch resistant material layer and the patterned photoresist layer after forming the etch resistant material layer. In an embodiment, the etch resistant material layer includes a binder component, a crosslinker component, and a etch resistant component bound together. In an embodiment, the binder component includes one or more selected from the group consisting of a phosphonic acid; a silane; a monodentate ligand moiety having a functional group selected from the group consisting of —OH, —NH₂, —SH, —CN, an alkane, an alkene, and a piperazine; a bidentate ligand moiety having one or more functional groups selected from the group consisting of —COOH, —CON(H)R, and a catechol; and a heteroatomic ligand moiety having one or more groups selected from a pyridine group, a bipyridine group, a terpyridine group, a pyrrole group, an imidazole group, a purine group, a pyrimidine group, a pyrazine group, and a thiophene group. In an embodiment, the crosslinker component includes a crosslinker moiety including one or more selected from the group consisting of an epoxy group, an oxetane group, a benzyl alcohol group, a benzyl ether group, an alkene group, an alkyne group, an acrylate group, a methacrylate group, and a melamine group. In an embodiment, the etch resistant component includes one or more selected from the group consisting of a polyhedric oligomeric silsesquioxane, a silane, a phosphonic acid, a metal oxide, a metal oxide cage structure, and an organometallic.

Another embodiment of the disclosure is a method of manufacturing a semiconductor device, including forming a metallic photoresist layer over a substrate and patternwise exposing the metallic photoresist layer to actinic radiation to form a latent pattern in the metallic photoresist layer. The patternwise exposed metallic photoresist layer is developed to form a patterned metallic photoresist layer. A post-development treatment is applied to the patterned metallic photoresist layer. The post-development treatment planarizes a surface of the patterned metallic photoresist layer and increases an etching resistance of the metallic photoresist layer. In an embodiment, the post-development treatment includes applying an etch resistant material to the metallic photoresist layer by a vapor deposition operation to form an etch resistant material layer. In an embodiment, the method includes heating the etch resistant material layer and the patterned metallic photoresist layer. In an embodiment, the etch resistant material includes one or more selected from the group consisting of [(CH₃)₃Si]₂NH, SiₓR¹_{y}(OR²)_{z}, SiₓR¹_{y}(NR²R³)_{z}, SnR¹_{y}(OR²)_{z}, and SnₓR¹_{y}(NR²R³)_{z}; where x is an integer from 1 to 20; y and z are integers, where y+z=4x; and R1, R2, and R3 are independently H, a C1-C20 alkyl, and a C1-C20 fluoroalkyl. In an embodiment, at least one of R1, R2, and R3 is a linear, cyclic, or branched C1-C20 alkyl or linear, cyclic, or branched C1-C20 fluoroalkyl.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a metallic resist layer over a substrate;
patterning the metallic resist layer to form a metallic resist pattern over the substrate; and
applying an etch resistant layer composition including an inorganic component, an organic component, or combination thereof over the metallic resist pattern to form an etch resistant layer.

2. The method according to claim 1, wherein the etch resistant layer includes a combination of the inorganic component and the organic component, and the organic component is bound to the inorganic component.

3. The method according to claim 1, wherein the etch resistant layer includes the inorganic component and the inorganic component includes one or more selected from the group consisting of silicon, phosphorus, or a metal.

4. The method according to claim 3, wherein the inorganic component includes the metal, and the metal includes one or more selected from the group consisting of Sn, Sb, Bi, In, Te, Zn, Ti, Zr, Hf, V, Co, Mo, W, Al, Ga, Si, Ge, As, Y, La, Ce, and Lu.

5. The method according to claim 1, wherein the etch resistant layer includes the inorganic component and the inorganic component has a three-dimensional cage structure.

6. The method according to claim 1, wherein the etch resistant layer includes the inorganic component and the inorganic component includes one or more selected from the group consisting of a polyhedric oligomeric silsesquioxane, a silane, a phosphonic acid, a metal oxide, a metal oxide cage structure, and an organometallic.

7. The method according to claim 1, wherein the etch resistant layer includes the inorganic component and the inorganic component includes one or more selected from the group consisting of [(CH₃)₃Si]₂NH, SiₓR¹_{y}(OR²)_{z}, SiₓR¹_{y}(NR²R³)_{z}, SnR¹_{y}(OR²)_{z}, and SnₓR¹_{y}(NR²R³)_{z}; where x is an integer from 1 to 20; y and z are integers, where y+z=4x; and R1, R2, and R3 are independently H, a C1-C20 alkyl, and a C1-C20 fluoroalkyl.

8. The method according to claim 7, wherein at least one of R1, R2, and R3 is a linear, cyclic, or branched C1-C20 alkyl or linear, cyclic, or branched C1-C20 fluoroalkyl.

9. The method according to claim 1, wherein the etch resistant layer includes the organic component and the organic component includes a crosslinker moiety including one or more selected from the group consisting of an epoxy group, an oxetane group, a benzyl alcohol group, a benzyl ether group, an alkene group, an alkyne group, an acrylate group, a methacrylate group, and a melamine group.

10. The method according to claim 1, wherein the etch resistant layer includes the organic component and the organic component includes a ligand moiety and the ligand moiety is a monodentate ligand moiety, a bidentate ligand moiety, or a heteroatomic ligand moiety,
wherein the monodentate ligand moiety has a functional group selected from the group consisting of —OH, —NH₂, —SH, —CN, an alkane, an alkene, and a piperazine;
the bidentate ligand moiety has one or more functional groups selected from the group consisting of —COOH, —CON(H)R, and a catechol; and
the heteroatomic ligand moiety has one or more groups selected from a pyridine group, a bipyridine group, a terpyridine group, a pyrrole group, an imidazole group, a purine group, a pyrimidine group, a pyrazine group, and a thiophene group.

11. A method of manufacturing a semiconductor device, comprising:
forming a photoresist layer over a substrate;
selectively exposing the photoresist layer to actinic radiation to form a latent pattern in the photoresist layer;
developing the latent pattern by applying a developer composition to the selectively exposed photoresist layer to form a patterned photoresist layer; and
forming an etch resistant material layer over the patterned photoresist layer.

12. The method according to claim 11, wherein the etch resistant material layer is formed by a vapor deposition operation.

13. The method according to claim 11, further comprising heating the etch resistant material layer and the patterned photoresist layer after forming the etch resistant material layer.

14. The method according to claim 11, wherein the etch resistant material layer comprises a binder component, a crosslinker component, and an etch resistant component bound together.

15. The method according to claim 14, wherein the binder component includes one or more selected from the group consisting of a phosphonic acid; a silane; a monodentate ligand moiety having a functional group selected from the group consisting of —OH, —NH₂, —SH, —CN, an alkane, an alkene, and a piperazine; a bidentate ligand moiety having one or more functional groups selected from the group consisting of —COOH, —CON(H)R, and a catechol; and a heteroatomic ligand moiety having one or more groups selected from a pyridine group, a bipyridine group, a terpyridine group, a pyrrole group, an imidazole group, a purine group, a pyrimidine group, a pyrazine group, and a thiophene group.

16. The method according to claim 14, wherein the crosslinker component includes a crosslinker moiety including one or more selected from the group consisting of an epoxy group, an oxetane group, a benzyl alcohol group, a benzyl ether group, an alkene group, an alkyne group, an acrylate group, a methacrylate group, and a melamine group.

17. The method according to claim 14, wherein the etch resistant component includes one or more selected from the group consisting of consisting of a polyhedric oligomeric silsesquioxane, a silane, a phosphonic acid, a metal oxide, a metal oxide cage structure, and an organometallic.

18. A method of manufacturing a semiconductor device, comprising:
forming a metallic photoresist layer over a substrate;
patternwise exposing the metallic photoresist layer to actinic radiation to form a latent pattern in the metallic photoresist layer;
developing the patternwise exposed metallic photoresist layer to form a patterned metallic photoresist layer; and
applying a post-development treatment to the patterned metallic photoresist layer,
wherein the post-development treatment planarizes a surface of the patterned metallic photoresist layer and increases an etching resistance of the metallic photoresist layer.

19. The method according to claim 18, wherein the post-development treatment includes applying an etch resistant material to the metallic photoresist layer by a vapor deposition operation to form an etch resistant material layer.

20. The method according to claim 19, wherein the etch resistant material includes one or more selected from the group consisting of [(CH₃)₃Si]₂NH, SiₓR¹_{y}(OR²)_{z}, SiₓR¹_{y}(NR²R³)_{z}, SnR¹_{y}(OR²)_{z}, and SnₓR¹_{y}(NR²R³)_{z}; where x is an integer from 1 to 20; y and z are integers, where y+z=4x; and R1, R2, and R3 are independently H, a C1-C20 alkyl, and a C1-C20 fluoroalkyl.
